(19) United States
(12) Patent Application Publication
(10) Pub. No.: US 2018/0295727 A1
(43) Pub. Date: Oct. 11, 2018

(54) Automatic Thin Film Peeling Machine and Thin Film Peeling Method Thereof

(71) Applicant: TOMORT AUTOMATION CO., LTD., TAOYUAN CITY (TW)

(72) Inventor: Ching-Chih CHANG, TAOYUAN CITY (TW)

(21) Appl. No.: 15/717,112

(22) Filed: Sep. 27, 2017

(30) Foreign Application Priority Data
Apr. 7, 2017 (TW) 106111783

(51) Int. Cl. H05K 3/00; B32B 43/00; H05K 13/00

(52) U.S. Cl. CPC H05K 3/0079; B32B 43/006; B32B 2457/08; H05K 13/0015; H05K 13/0069

(57) ABSTRACT

An automatic thin film peeling machine and a thin film peeling method thereof. In the thin film peeling method, a conveying unit conveys a plate, a blocking unit blocks at a front edge of the plate, and a clamping unit at the same time clamps and positions the plate. A rolling unit is moved to roll the front edge of the plate to cause a front edge of at least one thin film to produce at least one crease parallel to the front edge of the plate. Meanwhile, a first blowing unit blows and lifts the crease produced at the front edge of the thin film. After the rolling unit and the clamping unit are restored, the plate is moved continuously to allow the thin film peeling unit to peel the thin film along the front edge of the thin film.

### FIELD OF THE INVENTION

The present invention relates in general to a thin film peeling machine, and more particularly, to an automatic thin film peeling machine capable of peeling a thin film from a photoresist layer of a printed circuit board and a thin film peeling method thereof.

### BACKGROUND OF THE INVENTION

In a manufacturing process of a printed circuit board, before a substrate is exposed, a photoresist layer and a thin film adhered on a surface of the photoresist layer are formed at each of upper and lower surfaces of the substrate. After the exposure, the thin films are removed to reveal the photoresist layers in order to perform subsequent development and etching processes.

In a method of a current thin film peeling machine, the surface of the thin film is primarily rolled and pressed by an embossing wheel, and the thin film is then peeled by a sticking wheel. However, during the process of applying a force on the embossing wheel for rolling, damages of the photoresist layers and the substrate can be easily caused by an excessively large force applied for rolling. Therefore, the Taiwan Patent Publication No. 201608946, “Peeling Machine and Rolling Device Thereof”, discloses a peeling machine for peeling a thin film. The peeling machine of the above disclosure primarily includes a conveying device, a rolling device and a peeling device. The conveying device conveys a plate member along a conveying direction. The rolling device includes a driving mechanism and a rolling member. The driving mechanism is capable of moving the rolling member along a rolling direction from a front end of the plate member to an outer surface of the plate member, so as to form an indentation in a thin film to destroy the adhesion between the thin film and a photoresist layer. When the rolling member departs from the thin film, an air chamber is formed between the thin film and the photoresist layer. The air chamber has an opening formed between the front end and the photoresist layer. The peeling device includes a clamping blowing mechanism and a peeling mechanism. The clamping blowing mechanism clamps a front protruding portion and blows air towards the opening to cause a part of the thin film near the front end to peel off from the photoresist layer. The peeling mechanism is for connecting the part of the film near the front end of to peel the thin film from the photoresist layer.

The above peeling machine is capable of increasing the efficiency of peeling a thin film. However, it is discovered that, during an actual process of peeling the thin film, an air chamber is formed between the thin film and the photoresist layer due to the extremely small thickness and fragility of the thin film. Further, when the opening of the air chamber is formed between the front end and the photoresist layer, by using the approach of clamping the protrusion by the clamping blowing mechanism to peel the part of the thin film near the front end, some brittle pieces of the thin film may still be adhered on the surface of the photoresist layer. Further, as the brittle pieces of the thin film have areas that are too small to be detected, such occurrence persists throughout the entire manufacturing process of the printed circuit board, leading to an inevitable result of discarding the substrate.

### SUMMARY OF THE INVENTION

In view of the above issues, the present invention provides a structure distinct from the prior art to overcome the issues of the prior art.

It is an object of the present invention to provide an automatic thin film peeling machine and a thin film peeling method thereof to solve the issues of the prior art. In the prior art, during a process of peeling the thin film by a conventional thin film peeling machine, some brittle pieces of a thin film are adhered on a surface of a photoresist layer in a way that a substrate needs to be discarded. Thus, using the present invention, the thin film can be smoothly and thoroughly peeled to enhance product quality and yield rate, while also effectively preventing increased costs caused by repeated processing or material waste caused by discarded substrates.

To achieve the above object, an automatic thin film peeling machine of the present invention includes a conveying unit, a blocking unit, a clamping unit, rolling unit, a first blowing unit and a thin film peeling unit. The conveying unit includes a front conveying section and a back conveying section, and is for conveying and moving a plate along a conveying direction from back to front. The blocking unit is located at a back end of the front conveying section, and is connected to a first driving device that moves the blocking unit to block at a front edge of a plate. The clamping unit is located between the back end of the front conveying section and the blocking unit, and is connected to a second driving device that moves the clamping unit to clamp and position the plate. The rolling unit is located at the back end of the front conveying section, and is connected to a third driving device that moves the rolling unit to roll a front edge of the plate to cause a front edge of at least one thin film to produce at least one crease parallel to the front edge of the plate. The first blowing unit is located at the back end of the front conveying section, and is connected to an air feeding device to blow and lift the at least one crease produced at the front edge of the at least one thin film. The thin film peeling unit is located at a front end of the back conveying section, and peels the at least one thin film along the front edge of the at least one thin film.

In implementation, the rolling unit includes at least one upper embossing wheel and at least one lower embossing wheel for respectively rolling the front edge of the at least one thin film. The first blowing unit includes a first upper blowing unit and a first lower blowing unit. The first upper blowing unit includes at least one first upper blowing opening. Between the direction of air blown from the first upper blowing opening and the plane forms an inclined angle, and the air is blow downwards from a front end towards a back end of the plate. The first lower blowing unit includes at least one first lower blowing opening. Between the direction of air blown from the first lower blowing opening and the plane forms an inclined angle, and the air is blown upwards from the front end towards the back end of the plate. The first upper blowing unit and the first lower blowing unit are formed on the rolling unit.

In implementation, the thin film peeling unit includes an upper peeling member and a lower peeling member. The upper peeling member and the lower peeling member are respectively located at upper and lower ends of the back conveying section, and are for peeling at least one thin film on the substrate. The upper peeling member includes a first upper belt wheel assembly and a second upper belt wheel assembly, which are adjacent to each other and rotate in opposite directions. The lower peeling member includes a first lower belt wheel assembly and a second lower belt wheel assembly, which are adjacent to each other and rotate in opposite directions.

In implementation, the present invention further includes a second blowing unit, which is located at a back end of the thin film peeling unit and is connected to an air feeding device. The second blowing unit includes a second upper blowing unit and a second lower blowing unit. The second upper blowing unit includes at least one second upper blowing opening. Between the direction of air blown from the second upper blowing opening and the plate forms an inclined angle, and the air is blown downwards from the front end towards the back end of the plate. The second lower blowing unit includes at least one second lower blowing opening. Between the direction of air blown from the second lower blowing opening and the plate forms an inclined angle, and the air is blown upwards from the front end towards the back end of the plate.

In implementation, the present invention further includes a support unit. The support unit includes a retractable rod, which is capable of retracting and extending axially, and is provided with an intermediate rolling cylinder at an upper end thereof.

A thin film peeling method of the automatic thin film peel machine of the present invention includes following steps. In step (a), the plate is placed on the front conveying section of the conveying unit to convey and move the plate along a conveying direction from back to front. In step (b), the blocking unit is driven by the first driving device to move and cause the blocking unit to block at the front edge of the plate, and the clamping unit is driven by the second driving device to clamp and position the plate. In step (c), the rolling unit is driven by the third driving device to move the rolling unit to roll on the front edge of the plate to cause the front edge of at least one thin film to produce at least one crease parallel to the front edge of the plate; and meanwhile, the first blowing unit is used to blow and lift the at least one crease produced at the front edge of the at least one thin film. In step (d), the rolling unit and the clamping unit are restored, and the plate is moved continuously along the conveying direction from back to front to allow the thin film peeling unit to peel the at least one thin film along the front edge of the at least one thin film.

The above and other aspects of the invention will become better understood with regard to the following detailed description of the preferred but non-limiting embodiments. The following description is made with reference to the accompanying drawings.

### BRIEF DESCRIPTION OF DRAWINGS

FIG. 1 is a perspective schematic diagram of a preferred embodiment of the present invention;

FIG. 2 is an enlarged partial view of part “a” in FIG. 1;

FIG. 3 is a section schematic diagram of a preferred embodiment of the present invention;

FIG. 4 is a schematic diagram according to a preferred embodiment of the present invention in use for conveying a plate;

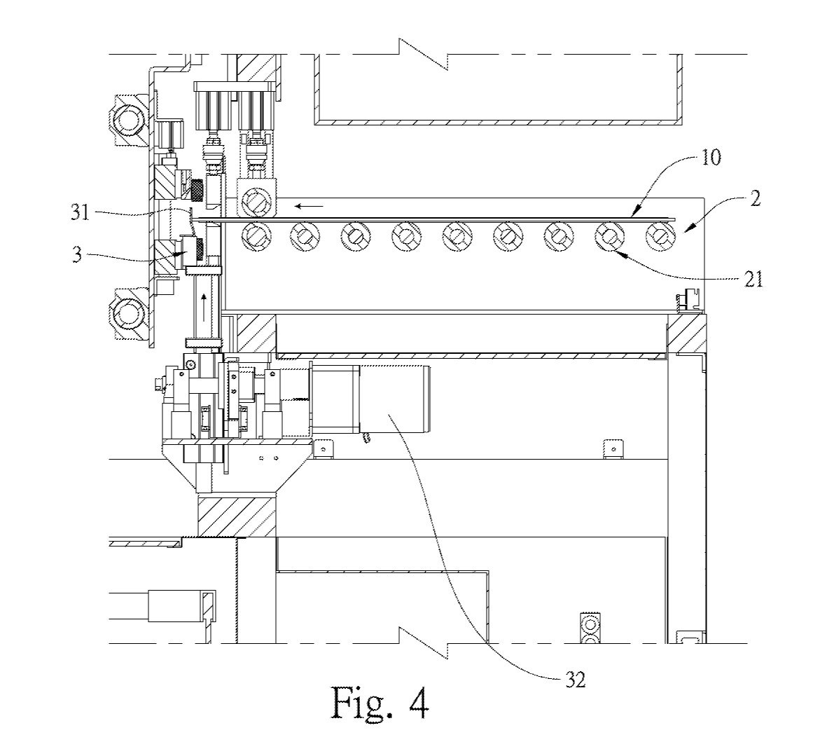

FIG. 5 is a schematic diagram according to a preferred embodiment of the present invention in use for conveying a plate, and a blocking unit blocking at a front edge of the plate;

FIG. 6 is an enlarged partial view of part “b” in FIG. 5 and a schematic diagram showing the use of a rolling unit rolling a front edge of a plate and a first blowing unit for blowing;

FIG. 7 is a schematic diagram showing the use of a thin film peeling unit curling and peeling a thin film and a second blowing unit for blowing according to a preferred embodiment of the present invention, and a schematic diagram; and

FIG. 8 is an enlarged partial view of part “c” in FIG. 7.

### DETAILED DESCRIPTIONS OF PREFERRED EMBODIMENTS

The present invention provides an automatic thin film peeling machine 1 for peeling at least one thin film 101 on a substrate of a plate 10. The at least one thin film 101 is combined on a photoresist layer of at least one side of the substrate. In implementation, one end at which the plate 10 is outputted is defined as a front end of the automatic thin film peeling machine 1, and one end at which the plate 10 is outputted is defined as a back end of the automatic thin film peeling machine 1. Further, one end close to a user is defined as a left side, and one end opposite to the left side and away from the user is defined as a right side. Further, a front end and a back end of the plate 10 are defined according to a progressing direction along which the plate 10 is conveyed.

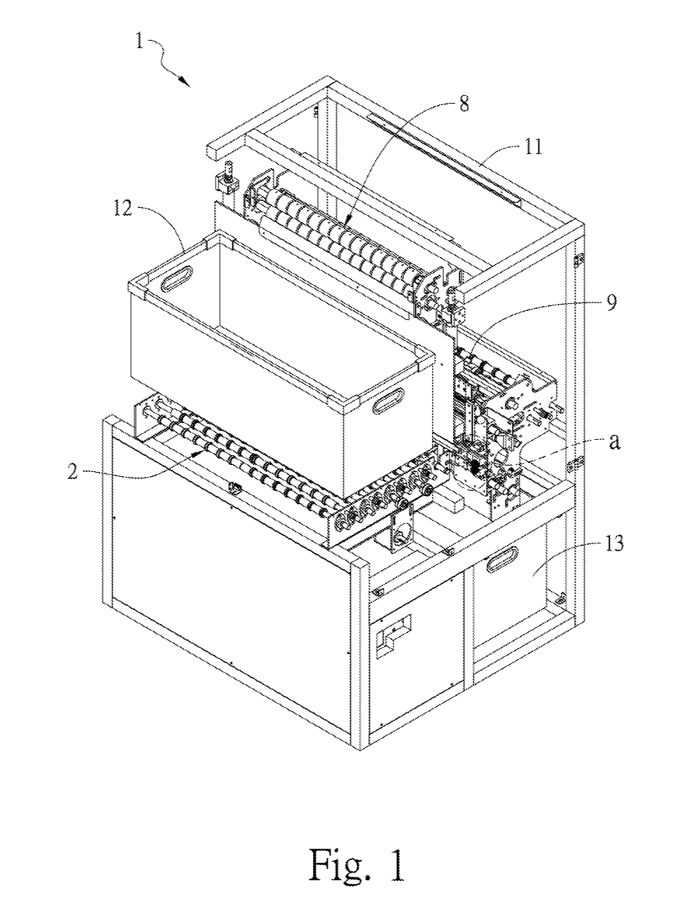

FIGS. 1 to 3 show the automatic thin film peeling machine 1 according to a preferred embodiment of the present invention. Referring to FIGS. 1 to 3, the automatic thin film peeling machine 1 includes a frame 11, a conveying unit 2, a blocking unit 3, a clamping unit 4, a rolling unit 5, a first blowing unit 6, a support unit 7, a thin film peeling unit 8 and a second blowing unit 9. The frame 11 is a rectangular body. An upper container 12 is provided above the conveying unit 2 at a front end of the frame 11, and a lower container 13 is provided below the conveying unit 2 at a back end of the frame 11.

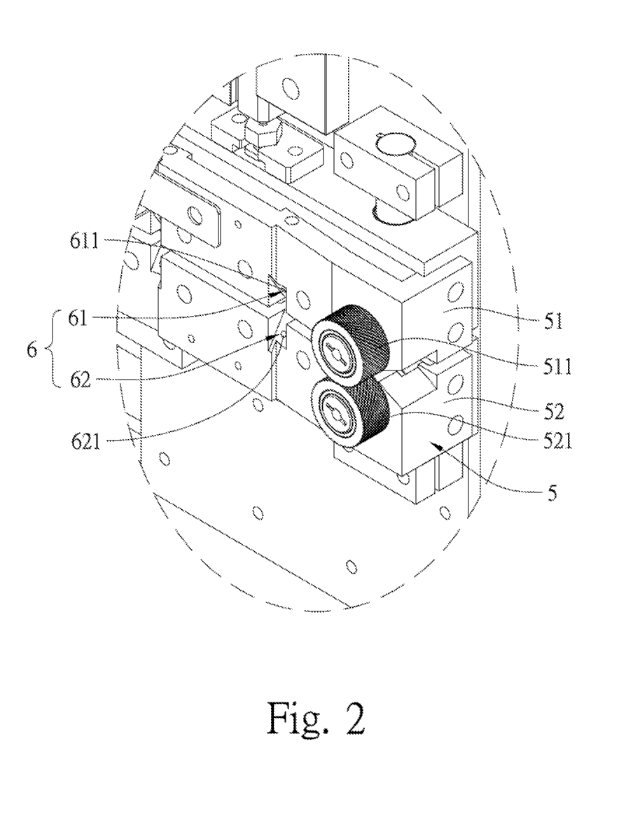

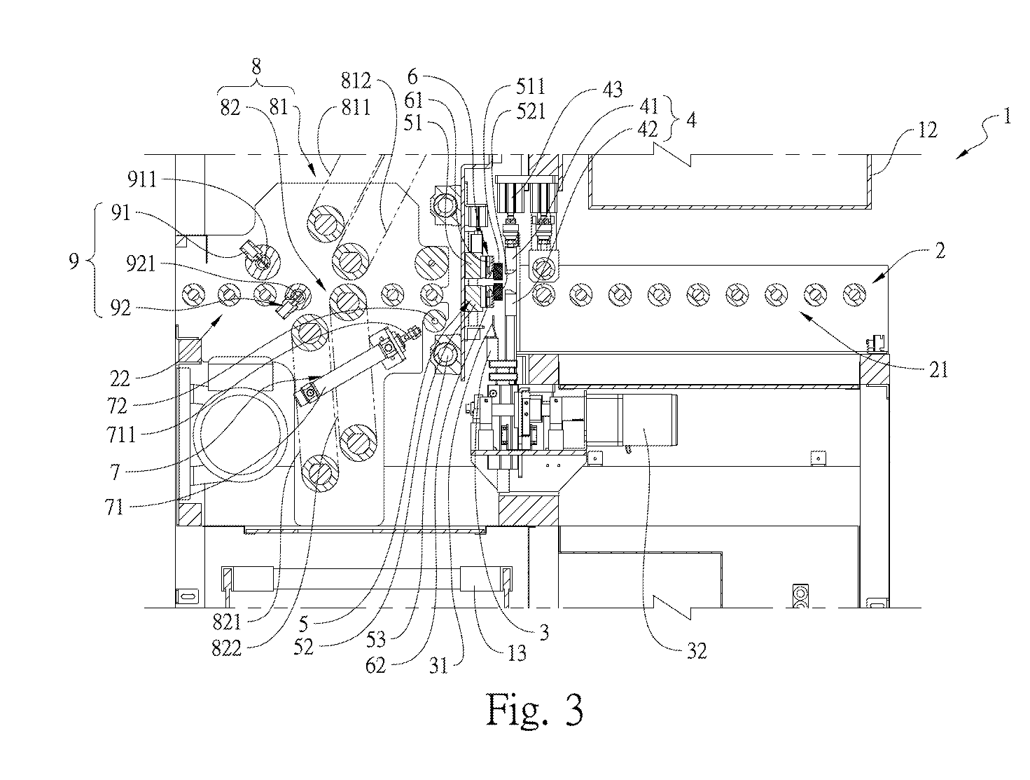

As shown in FIGS. 2 and 3, the conveying unit 2 is formed by a plurality of rolling cylinders horizontally arranged at a middle position of the frame 11, and includes a front conveying section 21 and a back conveying section 22 to convey and move the plate 10 along a conveying direction from back to front. The blocking unit 3 is located at a back end of the front conveying section 21, and has an upper part thereof extended upwards to form an upper plate 31. The blocking unit 3 is connected to a first driving device 32, which horizontally or vertically drives the blocking unit 3 to move the blocking unit 3 and cause the blocking unit 3 to block at a front edge of the plate 10. The clamping unit 4 is located between the back end of the front conveying section 3 and the blocking unit 3, and includes an upper clamping seat 41 and a lower clamping seat 42. The upper clamping seat 41 and the lower clamping seat 42 are connected to a second driving device 43, which causes upper clamping seat 41 and the lower clamping seat 42 to move upwards and downwards relative to each other to clamp and position of the plate 10. The rolling unit 5 is located between the front conveying section 21 and a back end of the clamping unit 4, and includes an upper seat 51 and a lower seat 52. A plurality of upper embossing wheels 511 are disposed at one side of a front end of the upper seat 51, and a plurality of lower embossing wheels 521 are disposed at one side of a front end of the lower seat 52. The upper seat 51 and the lower seat 52 are connected to a third driving device 53, which causes the upper seat 51 and the plurality of upper embossing wheels 511 as well as the lower seat 52 and the plurality of lower embossing wheels 521 to move relatively upwards or downwards. Meanwhile, the plurality of upper embossing wheels 511 and the plurality of lower embossing wheels 521 are caused to move back and forth once or multiple times along the front edge of the substrate, so as to respectively roll front edges of the thin films 101 at upper and lower sides of the substrate to cause each of the front edges of the two thin films 101 to produce a crease 102 parallel to the front edge of the plate 10. In implementation, each of the first driving device 32, the second driving device 43 and the third driving device 53 is a combination of a servo motor, a gear and a linking rod, a combination of air cylinders, or a combination of oil cylinders.

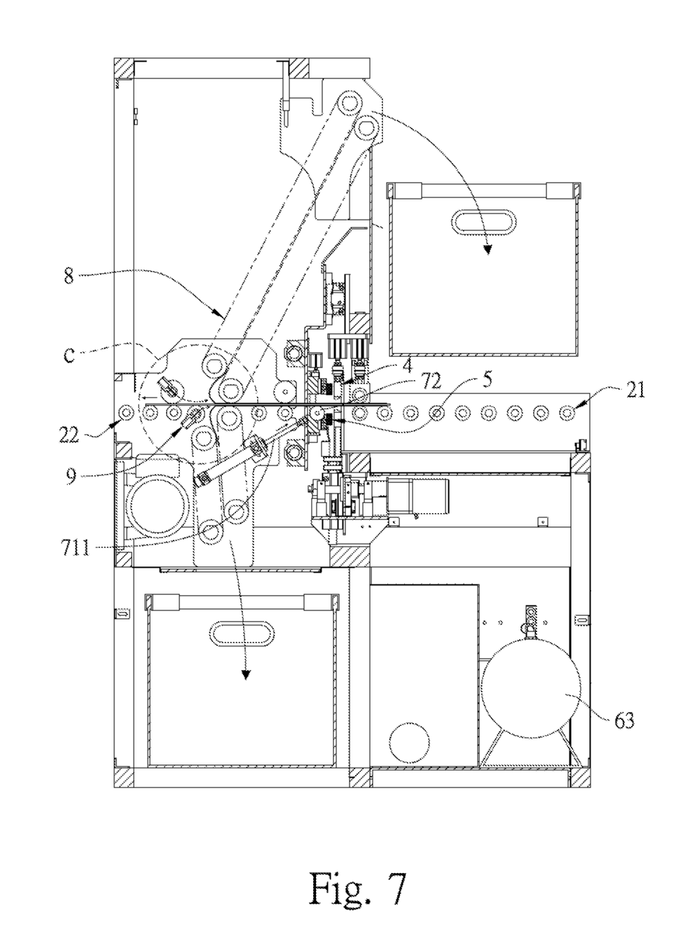

The first blowing unit 6 is located at the back end of the front conveying section 21, and includes a first upper blowing unit 61 and a first lower blowing unit 62. The first upper blowing unit 61 and the first lower blowing unit 62 are respectively located above and below the plate 10, and preferably, formed on the upper seat 51 and the lower seat 52 of the rolling unit 5, respectively. In implementation, the first upper blowing unit 61 and the first lower blowing unit 62 may also be separated from the upper seat 51 and the lower seat 52. The first upper blowing unit 61 and the first lower blowing unit 62 are connected to an air compressor, which serves as an air feeding device 63 (as shown in FIG. 7). The first upper blowing unit 61 includes a plurality of upper blowing openings 611. Between the direction of air blown from the plurality of upper blowing openings 611 and the plate 10 forms an inclined angle, and the air is blown downwards from the front end towards the back end of the plate 10, so as to blow and lift the crease 102 at the front edge of the thin film 101 at the top of the substrate. The first lower blowing unit 62 includes a plurality of lower blowing openings 621. Between the direction of air blown from the first lower blowing openings 611 and the plate 10 forms an inclined angle, and the air is blown upwards from the front end towards the back end of the plate 10, so as to blow and lift the crease 102 at the front edge of the thin film 101 at the bottom of the substrate.

The support unit 7 is slantingly fixed on the frame 11, and includes a pneumatic cylinder 71 and an intermediate rolling cylinder 72. The pneumatic cylinder 71 includes a retractable rod 711 capable of retracting and extending axially. The intermediate rolling cylinder 72 is connected to an upper end of the retractable rod 71, and is positioned between the front conveying section 21 and the back conveying section 22 when the retractable rod 711 is extended, so as to support and allow the plate 10 to continue moving along the horizontal direction.

The thin film peeling unit 8 includes an upper peeling member 81 and a lower peeling member 82. The upper peeling member 81 and the lower peeling member 82 are respectively located at upper and lower ends of the front end of the back conveying section 22. The upper peeling member 81 includes a first upper belt wheel assembly 811 and a second upper belt wheel assembly 812, which are adjacent to each other and rotate in opposite directions, in a way that the front edge of the thin film 101 at the top of the substrate is clamped between the two and becomes curled from top to bottom to fall into the upper container 12. The lower peeling member 82 includes a first lower belt wheel assembly 821 and a second lower belt wheel assembly 822, which are adjacent to each other and rotate in opposite directions, in a way that the front edge of the thin film 101 at the bottom of the substrate is clamped between the two and becomes curled from top to bottom to fall into the lower container 13.

The second blowing unit 9 is located at a back end of the thin film peeling unit 8, and includes a second upper blowing unit 91 and a second lower blowing unit 92. The second upper blowing unit 91 and the second lower blowing unit 92 are respectively located above and below the plate 10, and are connected to the air feeding device 63. The second upper blowing unit 91 includes a plurality of second upper blowing openings 911. Between the direction of air blown from the second upper blowing openings 911 and the plate 10 forms an inclined angle, and the air is blown downwards from the front end towards the backend of the plate 10. The second lower blowing unit 92 includes a plurality of second lower blowing openings 921. Between the direction of air from the second lower blowing openings 921 and the plate 10 forms an inclined angle, and the air is blown upwards from the front end towards the back end of the plate 10.

According to the structure of the above automatic thin film peeling machine 1, a thin film peeling method of the present invention includes following steps.

In step (a), the plate 10 is placed on the front conveying section 21 of the conveying unit 2 to be conveyed and moved along a conveying direction from back to front.

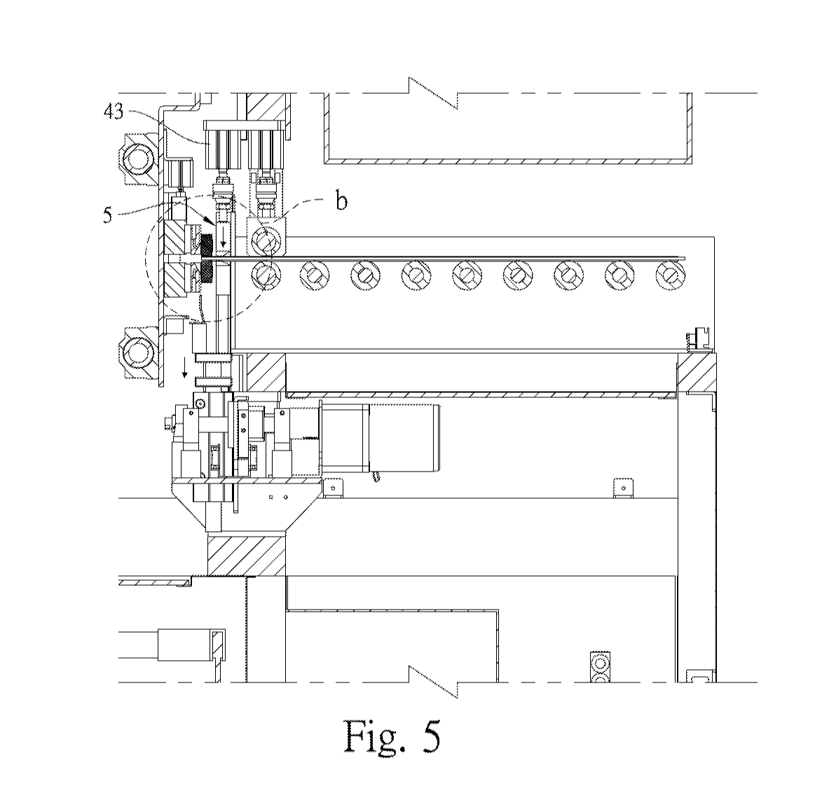

In step (b), the blocking unit 3 is driven by the first driving device 32 to move and cause the upper plate 31 of the blocking unit 3 to block at the front edge of the plate 5, and the clamping unit 4 is driven by the second driving device 43 to clamp and position the plate 10, as shown in FIG. 5.

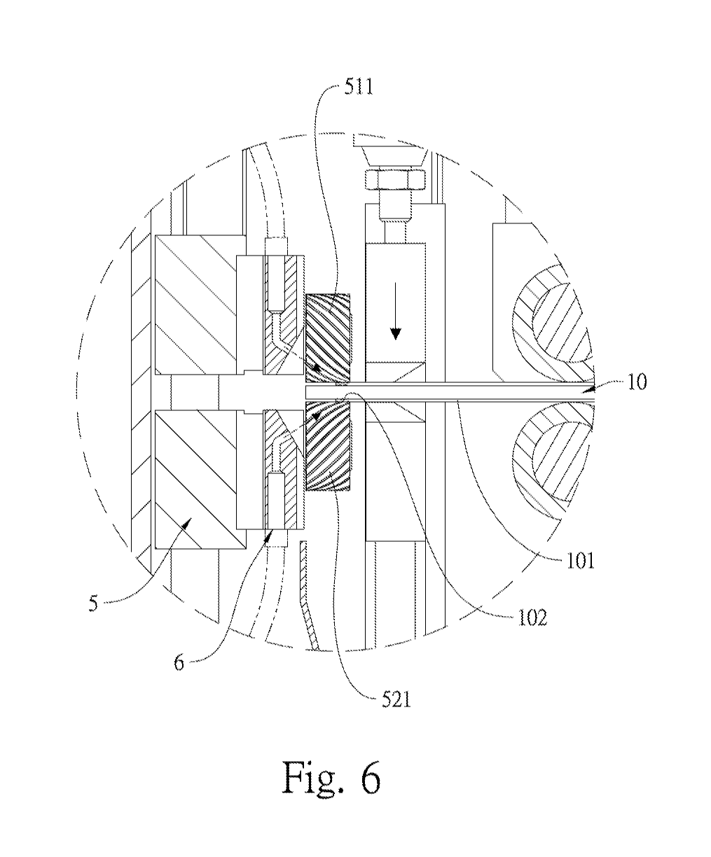

In step (c), as shown in FIG. 6, the rolling unit 5 is driven by the third driving device 53 to move the upper embossing wheels 511 and the lower embossing wheels 521 of the rolling unit 5 to roll the front edge of the plate 10, so as to cause the front edge of at least one thin film 101 to produce at least one crease 102 that is parallel to the front edge of the plate 10. Meanwhile, the first blowing unit 6 is used to blow and lift the at least one crease 102 produced at the front edge of the at least one thin film 101.

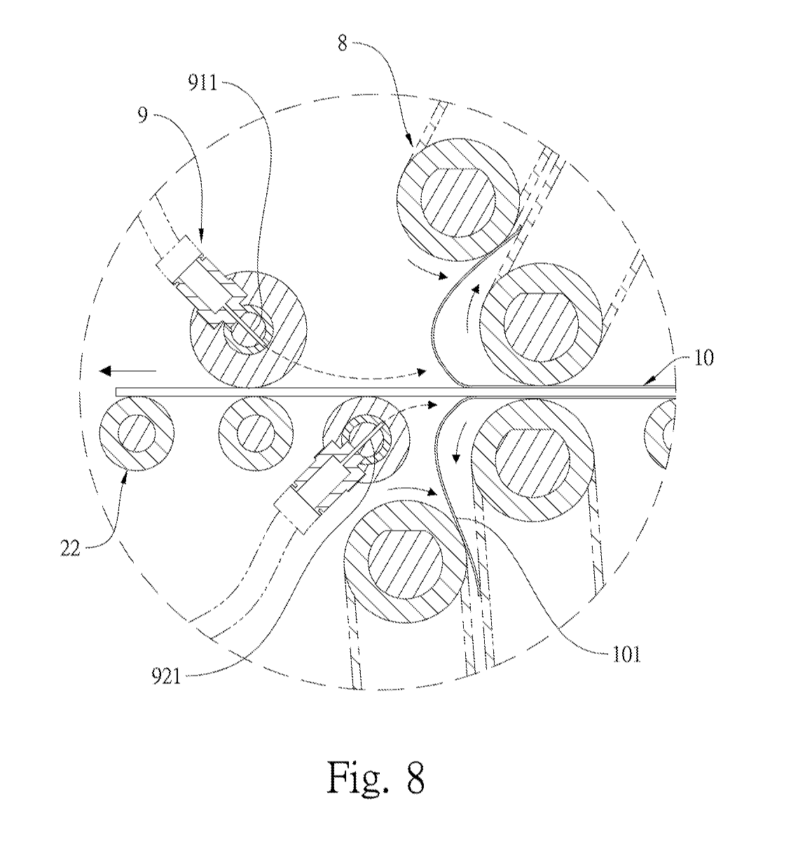

In step (d), as shown in FIG. 7 and FIG. 8, the rolling unit 5 and the clamping unit 4 are restored, and the retractable rod 711 is extended to position the intermediate rolling cylinder 72 between the front conveying section 21 and the back conveying section 22, so as to continuously move the plate 10 forward along the conveying direction from back to front. During the process that the thin film peeling unit 8 smoothly curls and peels the thin film 101 along the front edge of the thin film 101, the plurality of second upper blowing openings 911 of the second upper blowing unit 9 blow air downwards in a direction from the front end towards the back end of the plate 10, and the plurality of second lower blowing openings 921 of the second lower blowing unit 9 blow air upwards in a direction from the front end towards the back end of the plate 10, thereby causing at least one thin film 101 to be lifted backwards and gradually become peeled off.

Therefore, the present invention provides following advantages.

1. According to the present invention, when a crease that is parallel to the front edge of the plate is produced at the front edge of the thin film, the first blowing unit at the same time blows air towards the crease to lift the crease, and the thin film peeling unit then smoothly curls the front edge of the thin film to peel the thin film. Thus, the thin film can be thoroughly peeled without leaving residual brittle pieces of the thin film adhered on the substrate, thereby effectively enhancing the yield rate as well as preventing increased costs caused by repeated processing or material waste caused by discarded substrates.

2. During the process of peeling the thin film according to the present invention, two sets of belt wheel assemblies including elastic belts are used to clamp a front edge of a thin film, and air is simultaneously blown while the belt wheel assemblies rotate in reverse to gradually separate the thin film and the substrate. Thus, the force for peeling the thin film is more flexible, and is able to smoothly peel a thin film on a uniform or non-uniform plate.

In conclusion, based on the above disclosure, the present invention provides an automatic thin film peeling machine and a thin film peeling method thereof capable of smoothly and thoroughly peeling a thin film, hence achieving the expected object. While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An automatic thin film peeling machine, for peeling at least one thin film on a substrate of a plate; wherein, one end at which the plate is inputted is defined as a front end of the automatic thin film peeling machine, and one end at which the plate is outputted is defined as a back end of the automatic thin film peeling machine; the automatic thin film peeling machine comprising:
a conveying unit, comprising a front conveying section and a back conveying section, for conveying and moving the plate along a conveying direction from back to front;
a blocking unit, located at a back end of the front conveying section, connected to a first driving device that moves the blocking unit to block at a front edge of the plate;
a clamping unit, located between the back end of the front conveying section and the blocking unit, connected to a second driving device that moves the clamping unit to clamp and position the plate;
a rolling unit, located at the back end of the front conveying belt, connected to a third driving device that moves the rolling unit to roll the front edge of the plate, to cause a front edge of at least one thin film to produce at least one crease parallel to the front edge of the plate;
a first blowing unit, located at the back end of the front conveying section, connected to an air feeding device that blows and lifts the at least one crease produced at the front edge of the at least one thin film; and
a thin film peeling unit, located at a front end of the back conveying section, for peeling the at least one thin film along the front edge of the at least one thin film.

2. The automatic thin film peeling machine according to claim 1, wherein the rolling unit comprises at least one upper embossing wheel and at least one lower embossing wheel for respectively rolling the front edge of the at least one thin film.

3. The automatic thin film peeling machine according to claim 1, wherein the first blowing unit comprises a first upper blowing unit and a first lower blowing unit, the first upper blowing unit comprises at least one first upper blowing opening, between a direction of air blown from the first upper blowing opening and the plate forms an inclined angle, and the air blown from the first upper blowing opening is blown downwards from a front end towards a back end of the plate; the first lower blowing unit comprises at least one first lower blowing opening, between a direction of air blown from the first lower blowing opening and the plate forms an inclined angle, and the air blown from the first lower blowing opening is blown upwards from the front end towards the back end of the plate.

4. The automatic thin film peeling machine according to claim 3, wherein the first upper blowing unit and the first lower blowing unit are formed on the rolling unit.

5. The automatic thin film peeling machine according to claim 1, wherein the thin film peeling unit comprises an upper peeling member and a lower peeling member, and the upper peeling member and the lower peeling member are respectively located at upper and lower ends of the back conveying section to peel the at least one thin film on the substrate.

6. The automatic thin film peeling machine according to claim 5, wherein the upper peeling member comprises a first upper belt wheel assembly and a second upper belt wheel assembly, which are adjacent to each other and rotate in opposite directions; the lower peeling member comprises a first lower belt wheel assembly and a second lower belt wheel assembly, which are adjacent to each other and rotate in opposite directions.

7. The automatic thin film peeling machine according to claim 1, further comprising:
a second blowing unit, located at a back end of the thin film peeling unit, connected to an air feeding device, comprising a second upper blowing unit and a second lower blowing unit;
wherein, the second upper blowing unit comprises at least one second upper blowing opening, between a direction of air blown from the second upper blowing opening and the plate forms an inclined angle, and the air blown from the second upper blowing opening is blown downwards from a front end towards a back end of the plate; the second lower blowing unit comprises at least one second lower blowing opening, between a direction of air blown from the second lower blowing opening and the plate forms an inclined angle, and the air blown from the second lower blowing opening is blown upwards from the front end towards the back end of the plate.

8. The automatic thin film peeling machine according to claim 1, further comprising:
a support unit, comprising a retractable rod, which is capable of retracting and extending axially relative to the support unit and comprises an intermediate rolling cylinder at an upper end thereof.

9. A thin film peeling method performed by the automatic thin film peeling machine of claim 1, comprising steps of:
a) placing a plate on the front conveying section of the conveying unit to convey and move the plate along a conveying direction from back to front;
b) driving the blocking unit by the first driving device to move the blocking unit to block at the front edge of the plate, and driving the clamping unit by the second driving device to clamp and position the plate;
c) driving the rolling unit by the third driving device to move the rolling unit to roll the front edge of the plate to cause the front edge of the at least one thin film to produce the at least one crease at the front edge of the at least one thin film, and meanwhile, blowing and lifting, by the first blowing unit, the at least one crease produced at the front edge of the at least one thin film; and
d) restoring the rolling unit and the clamping unit, and causing the plate to continue moving along the conveying direction from back to front to allow the thin film peeling unit to peel the at least one thin film along the front edge of the at least one thin film.

10. The thin film peeling method according to claim 9, wherein in step (d), during the process of peeling the at least one thin film, air is blown downwards from at least one second upper blowing opening of a second upper blowing unit in a direction from a front end towards aback end of the plate, and air is blown upwards by at least one second lower blowing opening of a second lower blowing unit from the front end towards the back end of the plate to cause the at least one thin film to be lifted backwards.
